(19) United States
(12) Patent Application Publication
(10) Pub. No.: US 2026/0189210 A1
(43) Pub. Date: Jul. 2, 2026

(54) BULK ACOUSTIC WAVE DEVICE WITH TEMPERATURE COMPENSATION LAYER HAVING POSITIVE TEMPERATURE COEFFICIENT OF VARIATION

(71) Applicant: Skyworks Global Pte. Ltd., Singapore (SG)

(72) Inventors: Michael David Hill, Emmitsburg, MD (US); Alexandre Augusto Shirakawa, Cardiff by the Sea, CA (US); David Albert Feld, Los Altos, CA (US); Benjamin Paul Abbott, Irvine, CA (US); Martha Kennedy Small, Fort Collins, CO (US); Kwang Jae Shin, Yongin-si (KR)

(21) Appl. No.: 19/435,062

(22) Filed: Dec. 29, 2025

Related U.S. Application Data
(60) Provisional application No. 63/740,626, filed on Dec. 31, 2024.
(60) Provisional application No. 63/740,763, filed on Dec. 31, 2024.

(51) Int. Cl. H03H 9/02; H03H 9/135; H03H 9/17; H03H 9/56

(52) U.S. Cl. CPC H03H 9/02102; H03H 9/135; H03H 9/17; H03H 9/568

(57) ABSTRACT

Aspects of this disclosure relate to a bulk acoustic wave that includes a temperature compensation layer in thermal communication with a piezoelectric layer. The temperature compensation layer includes a silicon oxide composite that includes silicon oxide and a stiffening agent. The temperature compensation layer can have a positive temperature coefficient of variation. Related filters, multiplexers, radio frequency modules, radio frequency systems, wireless communication devices, and methods are disclosed.

### CROSS REFERENCE TO PRIORITY APPLICATIONS

Any and all applications for which a foreign or domestic priority claim is identified in the Application Data Sheet as filed with the present application are hereby incorporated by reference under 37 C.F.R. § 1.57. This application claims the benefit of priority of U.S. Provisional Application No. 63/740,626, filed Dec. 31, 2024 and titled “BULK ACOUSTIC WAVE DEVICE WITH TEMPERATURE COMPENSATION LAYER HAVING POSITIVE TEMPERATURE COEFFICIENT OF VARIATION,” and claims the benefit of priority of U.S. Provisional Application No. 63/740,763, filed Dec. 31, 2024 and titled “BULK ACOUSTIC WAVE DEVICE WITH SILICON OXYNITRIDE TEMPERATURE COMPENSATION LAYER,” the disclosures of each of which are hereby incorporated by reference in their entireties and for all purposes.

### BACKGROUND

### Technical Field

The disclosed technology relates to acoustic wave devices. Embodiments of this disclosure relate to acoustic wave devices with a temperature compensation layer having a positive temperature coefficient of variation and/or temperature coefficient of elasticity.

### Description of Related Technology

An acoustic wave filter can include a plurality of acoustic wave resonators arranged to filter a radio frequency signal. Example acoustic wave resonators include surface acoustic wave (SAW) resonators and bulk acoustic wave (BAW) resonators. A SAW resonator can include an interdigital transductor electrode on a piezoelectric substrate. The SAW resonator can generate a surface acoustic wave on a surface of the piezoelectric layer on which the interdigital transductor electrode is disposed. In BAW resonators, acoustic waves propagate in a bulk of a piezoelectric layer. Example BAW resonators include film bulk acoustic wave resonators (FBARs) and BAW solidly mounted resonators (SMRs).

Acoustic wave filters can be implemented in radio frequency electronic systems. For instance, filters in a radio frequency front end of a mobile phone can include acoustic wave filters. An acoustic wave filter can be a band pass filter. A plurality of acoustic wave filters can be arranged as a multiplexer. For example, two acoustic wave filters can be arranged as a duplexer.

In acoustic wave devices, temperature compensation can be desirable. For example, temperature compensated SAW (TCSAW) devices typically include a temperature compensation layer, such as a silicon dioxide layer, over and in contact with an interdigital transducer (IDT) electrode. Temperature compensated BAW (TCBAW) devices can also include a temperature compensation layer.

### SUMMARY OF CERTAIN INVENTIVE ASPECTS

The innovations described in the claims each have several aspects, no single one of which is solely responsible for its desirable attributes. Without limiting the scope of the claims, some prominent features of this disclosure will now be briefly described.

One aspect of this disclosure is a bulk acoustic wave device that includes a first electrode, a second electrode, a piezoelectric layer between the first electrode and the second electrode, and a temperature compensation layer in thermal communication with the piezoelectric layer. The temperature compensation layer includes a silicon oxide composite that includes silicon oxide and a stiffening agent. The temperature compensation layer has a positive temperature coefficient of variation.

The stiffening agent can include nitrogen. The stiffening agent can have a greater electronegativity than carbon. The stiffening agent can suppress a third order harmonic associated with the silicon oxide.

The temperature compensation layer can be positioned between the piezoelectric layer and either the first electrode or the second electrode.

The temperature compensation layer can be positioned between a surface of the first electrode and a surface of the second electrode.

The first electrode or the second electrode can be positioned between the temperature compensation layer and the piezoelectric layer.

The temperature compensation layer can be embedded in the first electrode or the second electrode. The electrode in which the temperature compensation layer is embedded can include portions on opposing sides of the temperature compensation layer, where the portions are electrically connected to each other.

The temperature compensation layer can be embedded in the piezoelectric layer.

The temperature compensation layer can be patterned.

The bulk acoustic wave device can include a support substrate and an acoustic reflector between the support substrate and the first electrode.

Another aspect of this disclosure is a bulk acoustic wave device that includes a first electrode, a second electrode, a piezoelectric layer between the first electrode and second electrode, and a temperature compensation layer in thermal communication with the piezoelectric layer. The temperature compensation layer includes silicon oxynitride. The temperature compensation layer has a positive temperature coefficient of variation.

The temperature compensation layer can be positioned between the piezoelectric layer and one of the electrodes.

The temperature compensation layer can be positioned between a surface of the first electrode and a surface of the second electrode.

One of the electrodes can be positioned between the temperature compensation layer and the piezoelectric layer.

The temperature compensation layer can be embedded in the first electrode or the second electrode. The electrode in which the temperature compensation layer is embedded can include portions on opposing sides of the temperature compensation layer, where the portions are electrically connected to each other.

The temperature compensation layer can be embedded in the piezoelectric layer.

The temperature compensation layer can be patterned.

Another aspect of this disclosure is a bulk acoustic wave device that includes a first electrode, a second electrode, a piezoelectric layer between the first and second electrodes, and a silicon oxynitride layer in thermal communication with the piezoelectric layer. The silicon oxynitride layer includes a nitrogen concentration of less than 15%.

The nitrogen concentration of the silicon oxynitride layer can be in a range from 2% to 11%. The nitrogen concentration of the silicon oxynitride layer can be in a range from 3% to 7%.

The silicon oxynitride layer can be positioned between the piezoelectric layer and the first electrode or the second electrode.

The silicon oxynitride layer can be positioned between a surface of the first electrode and a surface of the second electrode.

The first electrode can be positioned between the silicon oxynitride layer and the silicon oxynitride layer.

The second electrode can be positioned between the silicon oxynitride layer and the piezoelectric layer.

The silicon oxynitride layer can be embedded in the first electrode or the second electrode.

The silicon oxynitride layer can be embedded in the piezoelectric layer.

The silicon oxynitride layer can be patterned.

The bulk acoustic wave device can include a support substrate and an acoustic reflector between the support substrate and the first electrode.

Another aspect of this disclosure is a bulk acoustic wave device that includes a first electrode, a second electrode, a piezoelectric layer between the first and second electrodes, and a silicon oxynitride layer in thermal communication with the piezoelectric layer. The silicon oxynitride layer has a stiffness in a range from 80 gigapascals to 130 gigapascals at room temperature.

The stiffness of the silicon oxynitride layer can be in a range from 100 gigapascals to 120 gigapascals.

The silicon oxynitride layer can be positioned between the piezoelectric layer and the first electrode or the second electrode.

The silicon oxynitride layer can be positioned between a surface of the first electrode and a surface of the second electrode.

The first electrode can be positioned between the silicon oxynitride layer and the silicon oxynitride layer.

The second electrode can be positioned between the silicon oxynitride layer and the piezoelectric layer.

The silicon oxynitride layer can be embedded in the first electrode or the second electrode.

The silicon oxynitride layer can be embedded in the piezoelectric layer.

The silicon oxynitride layer can be patterned.

Another aspect of this disclosure is an acoustic wave filter for filtering a radio frequency signal. The acoustic wave filter includes a bulk acoustic wave device in accordance with any suitable principles and advantages disclosed herein and a plurality of additional acoustic wave resonators. The bulk acoustic wave device and the plurality of additional acoustic wave resonators are configured to filter the radio frequency signal.

Another aspect of this disclosure is a multiplexer for filtering radio frequency signals. The multiplexer includes a first filter including a bulk acoustic wave device in accordance with any suitable principles and advantages disclosed herein, and a second filter coupled to the first filter at a common node.

Another aspect of this disclosure is a radio frequency module that includes a filter including a bulk acoustic wave device in accordance with any suitable principles and advantages disclosed herein, radio frequency circuitry, and a package structure enclosing the filter and the radio frequency circuitry.

Another aspect of this disclosure is a radio frequency system that includes an antenna, a filter including a bulk acoustic wave device in accordance with any suitable principles and advantages disclosed herein, and an antenna switch configured to selectively electrically connect the antenna and a signal path that includes the filter.

Another aspect of this disclosure is a wireless communication device that includes a radio frequency front end including a filter that includes a bulk acoustic wave device in accordance with any suitable principles and advantages disclosed herein, an antenna coupled to the radio frequency front end, a transceiver in communication with the radio frequency front end, and a baseband system in communication with the transceiver.

Another aspect of this disclosure is a method of radio frequency signal processing. The method includes receiving a radio frequency signal at an input of the filter; and filtering the radio frequency signal with a filter that includes a bulk acoustic wave device in accordance with any suitable principles and advantages disclosed herein.

### BRIEF DESCRIPTION OF THE DRAWINGS

Embodiments of this disclosure will now be described, by way of non-limiting example, with reference to the accompanying drawings.

FIG. 1A is a schematic cross-sectional side view of a bulk acoustic wave (BAW) device according to an embodiment.

FIGS. 1B to 1H are schematic cross-sectional side views of an active region of different BAW device stack configurations according to embodiments.

FIG. 1I is a schematic top plan view of a BAW device according to an embodiment.

FIG. 2 is a schematic cross-sectional side view of a BAW device according to an embodiment.

FIG. 3A is a graph showing measurement data for BAW devices having a temperature compensation layer.

FIG. 3B is a graph showing measured quality factors of the BAW devices A-F and a BAW device that does not include a temperature compensation layer.

FIG. 3C is a graph showing measured Si—O stretching of the BAW devices used for the measurements of FIG. 3B.

FIG. 3D is a graph showing measured temperature coefficient of frequency (TCF) and coupling coefficient of the BAW devices used for the measurements of FIG. 3B.

FIG. 4A is a schematic cross-sectional side view of a BAW device according to an embodiment.

FIG. 4B is an enlarged view of a portion of the BAW device of FIG. 4A.

FIG. 5A is a schematic cross-sectional side view of a BAW device according to an embodiment.

FIG. 5B is an enlarged view of the BAW device of FIG. 5A.

FIGS. 6A and 6B are graphs showing simulated second and third harmonic mode frequency responses of BAW devices.

FIG. 7A is a schematic diagram of a ladder filter that includes an acoustic wave resonator according to an embodiment.

FIG. 7B is schematic diagram of an acoustic wave filter.

FIGS. 8A, 8B, 8C, and 8D are schematic diagrams of multiplexers that includes an acoustic wave resonator according to an embodiment.

FIGS. 9, 10, and 11 are schematic block diagrams of modules that include a filter with an acoustic wave device according to an embodiment.

FIG. 12 is a schematic block diagram of a wireless communication device that includes a filter with an acoustic wave device according to an embodiment.

### DETAILED DESCRIPTION OF CERTAIN EMBODIMENTS

The following description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings. Any suitable principles and advantages of the embodiments disclosed herein can be implemented together with each other.

Acoustic wave devices can include a temperature compensation layer. For example, bulk acoustic wave (BAW) resonators and filters are generally designed to operate within a temperature range of −40° C. to 150° C. Implementing frequency compensation across this temperature spectrum can enhance filter performance by enhancing and/or optimizing, for example, roll-off characteristics, reducing insertion loss, and minimizing die size. A temperature compensation layer can bring the temperature coefficient of frequency (TCF) of an acoustic wave device closer to zero relative to a similar acoustic wave device without the temperature compensation layer. The temperature compensation layer can have a positive temperature coefficient of elasticity (TCE). This can compensate for a piezoelectric layer of the acoustic wave device having a negative TCF. The temperature compensation layer can be in physical contact with at least a portion of the piezoelectric layer of an acoustic wave device and/or with an electrode of an acoustic wave device. Certain bulk acoustic wave (BAW) devices include a temperature compensation layer between an electrode and a piezoelectric layer. BAW devices that include a temperature compensation layer can be referred to as temperature compensated BAW (TCBAW) devices. Certain surface acoustic wave (SAW) devices include a temperature compensation layer over and in physical contact with an interdigital transducer (IDT) electrode. Such SAW devices can be referred to as temperature compensated SAW (TCSAW) devices.

A silicon dioxide (SiO₂) layer is used as a temperature compensation layer for an acoustic wave device in a variety of different applications. Such a silicon dioxide layer can also be referred to as amorphous silica or fused silica in various applications. Silicon dioxide is a material with an acoustic velocity and an elastic modulus that increase with temperature (positive temperature coefficient of elastic modulus). This can allow for temperature compensation with piezoelectric materials that have an acoustic velocity and an elastic modulus that decrease with temperature. An SiO₂ temperature compensation layer can stabilize a resonant frequency of a BAW device over the temperature range of use.

However, fused silica, such as SiO₂, can present technical challenges in certain acoustic wave filter stacks. Fused silica has a non-linear elastic modulus as a result of its atomic structure. This non-linearity in the elastic properties can lead to the generation of undesirable third order harmonics. As an electrical insulator, placement of fused silica in the stack can be constrained. Moreover, fused silica can exhibit an acoustic loss tangent of up to about 0.03 at 5 gigahertz (GHz), making fused silica a relatively high acoustic loss layer in the stack. This relatively high acoustic loss can negatively impact filter performance, as relatively low energy dissipation is significant for maintaining efficiency in acoustic wave filters. Additionally, the material's relatively low acoustic impedance can make it difficult to achieve optimal impedance matching in various stack configurations. Fused silica can also be mechanically brittle, which can make fused silica prone to fractures caused by thermal stresses, especially in high-power applications. These technical challenges in terms of electrical, acoustic, and mechanical properties can make fused silica less ideal as a temperature compensating material for certain acoustic wave filters.

Certain approaches have utilized fused silica or doped fused silica for temperature compensation in filters. Other brittle glasses, such as fused germania and fused tellurium oxide, have also been explored. However, these alternatives share similar drawbacks, which can include high resistivity, poor acoustic loss performance, low acoustic impedance, and mechanical brittleness, which can limit their utility in acoustic wave filter applications.

Embodiments disclosed herein relate to acoustic wave devices with a temperature compensation layer that includes a silicon oxide-based composite having an additive that increases the stiffness or Young's modulus as compared to silicon oxide. An acoustic wave device according to some embodiments can be a bulk acoustic wave device that includes a first electrode, a second electrode, a piezoelectric layer between the first and second electrodes, and the temperature compensation layer in thermal communication with the piezoelectric layer. The additive in the temperature compensation layer can be a stiffening agent, such as nitrogen. The silicon oxide-based composite can be silicon oxynitride. A concentration of nitrogen in silicon oxynitride can be selected so that the silicon oxynitride layer has a positive temperature coefficient of variation. Silicon oxynitride temperature compensation layers disclosed herein can reduce elastic non-linearities compared to fused silica while retaining a positive temperature coefficient of elastic modulus. With such temperature compensation layers, third order harmonic generation can be suppressed compared to fused silica.

The doping of nitrogen into fused silica can reduce elastic non-linearities of fused silica while retaining the positive temperature coefficient of the elastic modulus. Doping nitrogen into fused silica can reduce the temperature coefficient of the acoustic velocity. The temperature coefficient of acoustic velocity can remain positive for silicon oxynitride layer for levels below about a 0.06 nitrogen ratio relative to oxygen.

Doping nitrogen can improve the bond strength and cross-linking in the vitreous structure. Each nitrogen atom can bond to three silicon atoms instead of two silicon atoms for every oxygen atom. The improved bond strength and cross-linking from doping with nitrogen can make the structure more rigid and reduce bond angle flexibility, which can occur in fused silica. This bond angle flexibility is thought to be responsible for the elastic non-linearity in fused silica.

Silica targets may be used and the ratio of nitrogen to oxygen flow rates during sputtering can be adjusted to produce a desired silicon oxynitride composition.

Since the temperature coefficient of acoustic velocity can be lower in the silicon oxynitride film, a thicker silicon oxynitride temperature compensating film may be desired.

Relatively large increases in the elastic modulus are observed for modest nitrogen doping levels. Third order harmonics can be suppressed at nitrogen levels in silicon oxynitride temperature compensation layers that have a positive temperature coefficient of acoustic velocity. This disclosure provides temperature compensation layers with a linear elastic modulus over a relatively wide strain range while achieving a positive temperature coefficient of acoustic velocity.

Any suitable principles and advantages disclosed herein can be implemented in any types of acoustic wave devices such as BAW devices or SAW devices, or timing devices with, for example, zero drift BAW or SAW resonators.

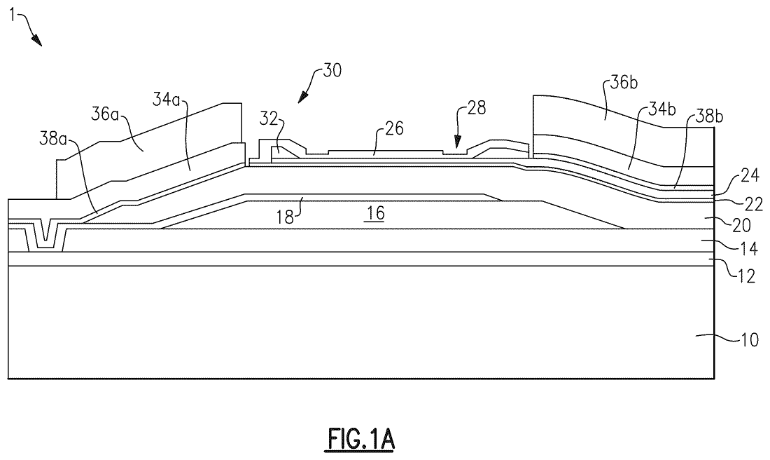

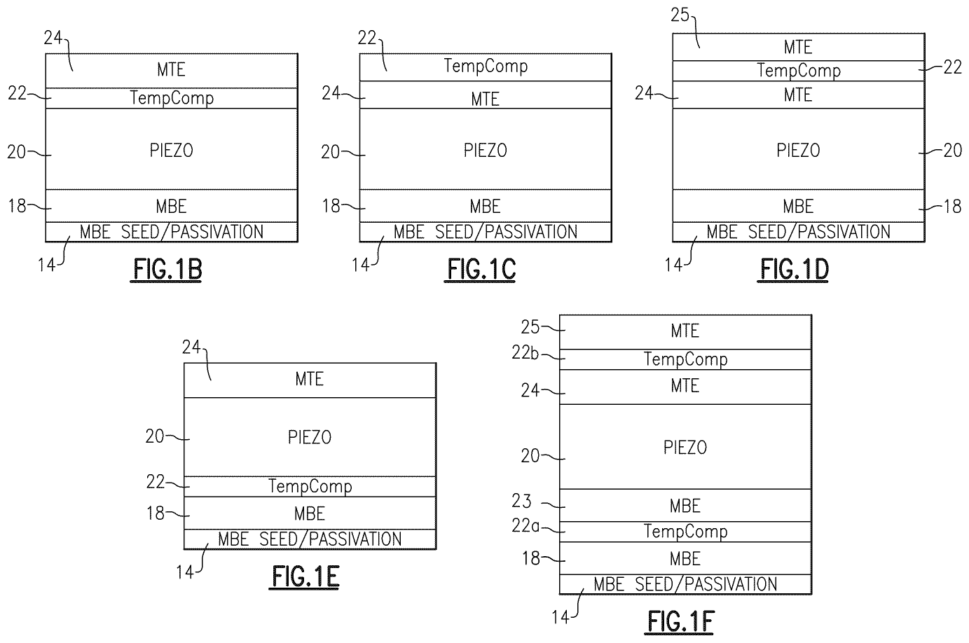

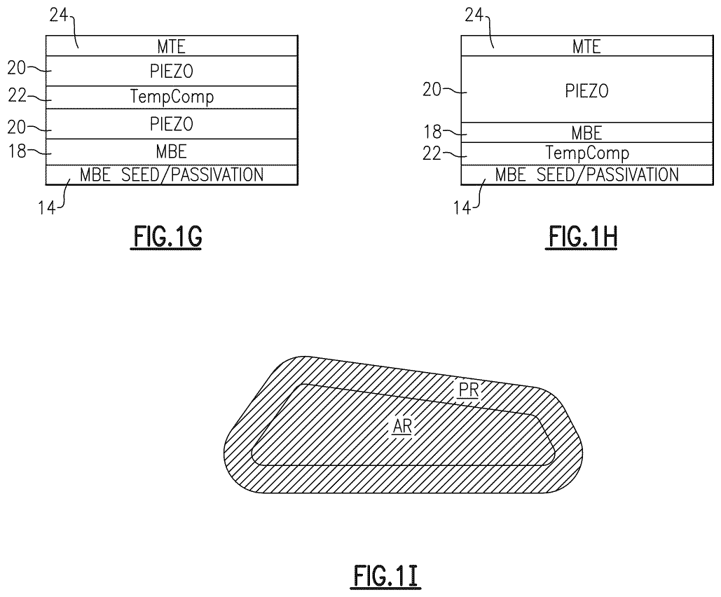

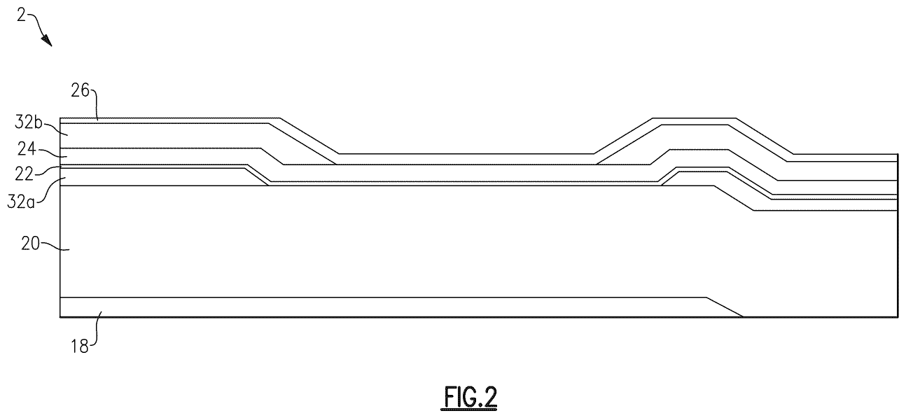

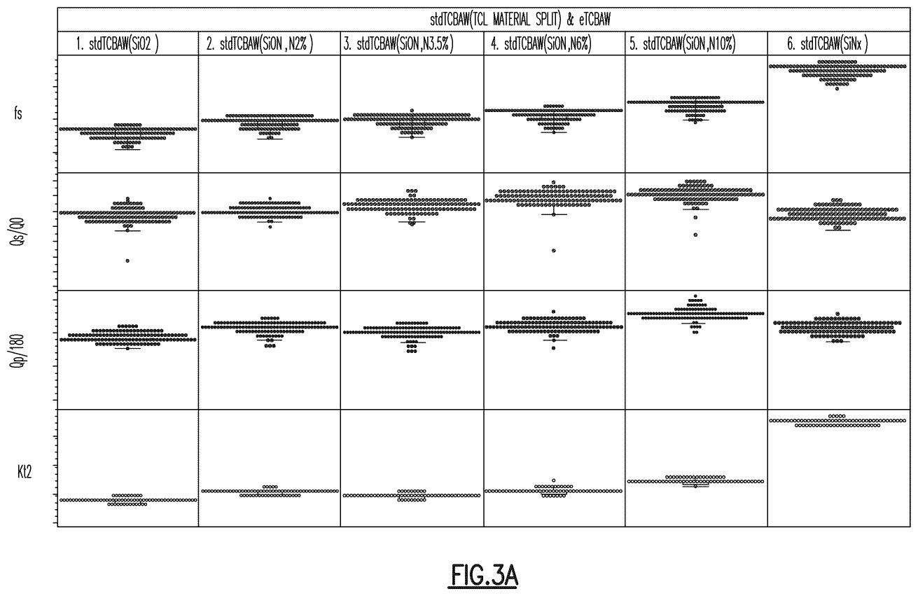

FIG. 1A is a schematic cross-sectional side view of a BAW device 1 according to an embodiment. The BAW device 1 includes a support substrate 10, a trap rich layer 12, a first passivation layer 14, a cavity 16, a first electrode 18, a piezoelectric layer 20, a temperature compensation layer 22, a second electrode 24, and a second passivation layer 26. The BAW device 1 also includes a recessed frame structure 28 and a raised frame structure 30. The temperature compensation layer 22 includes a silicon oxide-based composite having an additive that increases the stiffness or Young's modulus as compared to silicon oxide. Such an additive is a stiffening agent.

The temperature compensation layer 22 can bring the TCF of the BAW device 1 closer to zero. The temperature compensation layer 22 can have a positive temperature coefficient of variation (TCV) and/or a positive temperature coefficient of elasticity (TCE). The temperature compensation layer 22 can be in physical contact with the piezoelectric layer 20, for example, as shown in FIG. 1A. The temperature compensation layer 22 can be in physical contact with an electrode of the BAW device (e.g., the second electrode 24 in FIG. 1A). The temperature compensation layer 22 can be positioned in any other suitable locations in the BAW device 1. As illustrated, the temperature compensation layer 22 is positioned between an electrode of the BAW device 1 (e.g., the second electrode 24 in FIG. 1A) and the piezoelectric layer 20. In some other embodiments, the temperature compensation layer 22 can be positioned (1) between a piezoelectric layer and upper electrode (e.g., as illustrated in FIG. 1A), (2) between the piezoelectric layer and lower electrode, (3) embedded within a piezoelectric layer, (4) embedded within an electrode, or (5) any suitable combination(s) of (1) to (4).

The additive in the temperature compensation layer 22 can be a stiffening agent that increases the stiffness of the temperature compensation layer 22. For example, the stiffening agent can be nitrogen, and the silicon oxide-based composite can be silicon oxynitride. A concentration of nitrogen in silicon oxynitride can be selected to have a positive temperature coefficient of variation (TCV).

Table 1 below shows the longitudinal stiffness (C_{L}) in gigapascal (GPa), the TCV in parts per million per Kelvin (ppm/K), and the vibrational frequency of the 4^{th} mode (ω4) in reciprocal centimeters (cm⁻¹) of silicon oxide and silicon oxynitrides with different nitrogen concentrations.

TABLE 1

| | | Temperature | Vibrational |
|---|---|---|---|
| | Longitudinal | Coefficient | Frequency |
| | Stiffness | of Variation | of 4^{th} mode |
| | (GPa) | (ppm/K) | (cm⁻¹) |
| SiO_{1.81}N_{0.19} | 141 | −0.64 | 1030.9 |
| SiO_{1.88}N_{0.12} | 121.3 | 11.8 | 1041.4 |
| SiO_{1.93}N_{0.07} | 110.8 | 56.5 | 1048.1 |
| SiO₂ | 79 | 69.9 | 1064.5 |

Table 1 indicates that including nitrogen with a silicon oxide increases longitudinal stuffiness. Table 1 also indicates that including nitrogen with a silicon oxide decreases vibrational frequency of the 4^{th} mode. For certain silicon oxynitrides including SiO_{1.88}N_{0.12} and SiO_{1.93}N_{0.07}, a positive TCV can be achieved.

A nitrogen ratio of a silicon oxynitride can be N/(O+N), where N is the number for nitrogen in the formula for silicon oxynitride and O is the number for oxygen in the formula for silicon oxynitride. For example, the nitrogen ratio is about 0.06 for SiO_{1.88}N_{0.12}. As another example, the nitrogen ratio is 0.035 for SiO_{1.93}N_{0.07}. The concentration of nitrogen can correspond to the number of N in the formula for silicon oxynitride. For example, the concentration of nitrogen is 12% for SiO_{1.88}N_{0.12}. As another example, the nitrogen concentration is 7% for SiO_{1.93}N_{0.07}.

In some embodiments, the concentration of nitrogen in the temperature compensation layer 22 can be less than 15%, less than 12%, less than 11%, less than 10%, less than 7%, or less than 4%. For example, the concentration of the nitrogen in the temperature compensation layer 22 can be in a range from 1% to 15%, 2% to 12%, 2% to 11%, 3% to 7%, or 1% to 4%. In some embodiments, the concentration of nitrogen can be controlled by, for example, the nitrogen doping duration and/or the nitrogen doping strength.

The stiffening agent can have an electronegativity greater than the electronegativity of carbon. Higher electronegativity can lead to stronger bonds between silicon oxide and the stiffening agent. In some applications, suitable materials other than nitrogen, such as but not limited to fluorine, may be used as the stiffening agent. Both nitrogen and fluorine have higher electronegativity than carbon.

In some embodiments, the stiffness of the temperature compensation layer 22 at room temperature can be in a range from 80 GPa to 130 GPa, 90 GPa to 130 GPa, 100 GPa to 130 GPa, 110 GPa to 130 GPa, 100 GPa to 120 GPa, or 110 GPa to 120 GPa. Increased stiffness due to a stiffening agent in the temperature compensation layer can reduce elastic non-linearities while retaining a positive temperature coefficient of elastic modulus. Increased stiffness due to a stiffening agent in the temperature compensation layer can suppress third order harmonic generation in acoustic wave devices, such as BAW devices. The stiffness of the temperature compensation layer 22 can change with temperature, and the rate of the change can be described as a temperature coefficient of the elastic modulus. In some embodiments, the TCV of the temperature compensation layer 22 can be in a range from 5 ppm/K to 65 ppm/K, 5 ppm/K to 55 ppm/K, 5 ppm/K to 45 ppm/K, 10 ppm/K to 65 ppm/K, 20 ppm/K to 65 ppm/K, or 40 ppm/K to 55 ppm/K.

Although the temperature compensation layer 22 is illustrated as being a single layer structure, there may be multiple temperature compensation layers provided in a BAW device. For example, a BAW device can include a temperature compensation structure that includes a silicon oxide layer and a silicon oxynitride layer. As another example, a BAW device can include a temperature compensation structure that includes two or more silicon oxynitride layers. When a temperature compensation structure includes multiple temperature compensation layers, the overall TCV of the temperature compensation structure can be positive. Precisely controlling the concentration of the stiffening agent (e.g., nitrogen) in a relatively thin layer can be challenging. However, by implementing multiple temperature compensation layers, the overall TCV of the temperature compensation structure may be controlled more easily. One or more temperature compensation layers including the temperature compensation layer 22 can be positioned at any suitable location in the BAW device 1.

The support substrate 10 can be a semiconductor substrate, such as a silicon substrate. The support substrate 10 can be a high resistivity silicon substrate. The support substrate 10 can be any other suitable support substrate, such as a substrate of quartz, silicon carbide, sapphire, glass, gallium arsenide, or any suitable ceramic (e.g., spinel, alumina, etc.).

The trap rich layer 12 can be a polysilicon layer, an amorphous silicon layer, or the like. The trap rich layer 12 can be positioned between the support substrate 10 and the first passivation layer 14. The first passivation layer 14 can be referred to as a lower passivation layer. The first passivation layer 14 can be a buried oxide layer. The first passivation layer 14 can be an amorphous silicon oxycarbide layer in certain applications. In some other applications, the first passivation layer 14 can be a silicon dioxide layer or any other suitable passivation layer, such as aluminum oxide, silicon carbide, aluminum nitride, silicon nitride, silicon oxynitride, or the like. In some instances, a silicon dioxide layer can be over a trap rich layer and an amorphous silicon oxycarbide layer can be over the silicon dioxide layer. In some embodiments, the first passivation layer 14 can be provided between the cavity 16 and the first electrode 18.

The cavity 16 is an example of an acoustic reflector. The cavity 16 can be an air cavity. As illustrated in FIG. 1A, the cavity 16 is located above the support substrate 10. The cavity 16 is positioned between the support substrate 10 and the first electrode 18. In some applications, a cavity can be etched into a support substrate. In certain applications, a solid acoustic mirror with alternating high acoustic impedance and low acoustic impedance can be included in place of an air cavity. A BAW device with an air cavity can be referred to as an FBAR. A BAW device with a solid acoustic mirror (SMR) can be referred to as a BAW SMR.

The first electrode 18 can be referred to as a lower electrode or a bottom electrode. The first electrode 18 can have a relatively high acoustic impedance. The first electrode 18 can include molybdenum (Mo), tungsten (W), ruthenium (Ru), chromium (Cr), iridium (Ir), platinum (Pt), Ir/Pt, or any suitable alloy and/or combination thereof. The second electrode 24 can have a relatively high acoustic impedance. The second electrode 24 can include Mo, W, Ru, Cr, Ir, Pt, Ir/Pt, or any suitable alloy and/or combination thereof. The second electrode 24 can be formed of the same material as the first electrode 18 in certain instances. The second electrode 24 can be referred to as an upper electrode or a top electrode. The thickness of the first electrode 18 can be approximately the same as the thickness of the second electrode 24 in a main acoustically active region of the BAW device 1. The first electrode 18 and the second electrode 24 can be the only electrodes of the BAW device 1.

The piezoelectric layer 20 is positioned between the first electrode 18 and the second electrode 24. The piezoelectric layer 20 can include aluminum nitride or any other suitable piezoelectric material. The piezoelectric layer 20 can be doped with any suitable dopant, such as scandium (Sc), chromium (Cr), magnesium (Mg), sulfur(S), yttrium (Y), silicon (Si), germanium (Ge), oxygen (O), hafnium (Hf), zirconium (Zr), titanium (Ti), or the like. In certain instances, the piezoelectric layer 20 can be an aluminum nitride layer doped with scandium. Doping the piezoelectric layer 20 can adjust resonant frequency. Doping the piezoelectric layer 20 can increase the coupling coefficient k² of the BAW device 1. Doping to increase the coupling coefficient k² can be advantageous for wide band devices and/or high frequency devices where the coupling coefficient k² may be limited due to a thin resonator stack including a relatively thin piezoelectric layer thickness.

The second passivation layer 26 can be referred to as an upper passivation layer. The second passivation layer 26 can be referred to as a passivation and trimming layer, as the second passivation layer 26 can be used for both passivation and frequency trimming. The second passivation layer 26 can be a silicon dioxide layer, a silicon oxycarbide layer, or any other suitable passivation layer. The second passivation layer 26 can be the same material as the first passivation layer 26 in certain instances. The second passivation layer 26 can have different thicknesses in different regions of the BAW device 1. Part of the second passivation layer 26 can form at least part of the recessed frame structure 28 and/or the raised frame structure 30. In some embodiments, the raised frame structure 30 can include a raised frame layer 32. For example, the raised frame structure can include a metal layer or a dielectric layer.

An active region or active domain of the BAW device 1 can be defined by a portion of the piezoelectric layer 20 that overlaps an acoustic reflector, such as the cavity 16, and is between the first electrode 18 and the second electrode 24. The temperature compensation layer 22 can be positioned at least in the active region of the BAW device 1. The active region can correspond to where voltage is applied on opposing sides of the piezoelectric layer 20 over the acoustic reflector and a bulk acoustic wave is generated. The active region can be the acoustically active region of the BAW device 1. The BAW device 1 also includes a recessed frame region with the recessed frame structure 28 in the active region and a raised frame region with the raised frame structure 30 in the active region. The raised frame structure 30 can also include an oxide layer. The main acoustically active region can provide a main mode of the BAW device 1. The main mode can be the mode associated with the highest coupling or kt² of the BAW device 1. The main acoustically active region can be the central part of the active region that is free from frame structures, such as the recessed frame structure 28 and the raised frame structure 30.

While the BAW device 1 includes the recessed frame structure 28 and the raised frame structure 30, other frame structures can alternatively or additionally be implemented. For example, a raised frame structure with multiple layers including a layer between an electrode of a BAW device and a piezoelectric layer can be implemented. As another example, a floating raised frame structure can be implemented. As one more example, a raised frame structure can be implemented without a recessed frame structure.

One or more metal layers 34a, 34b, 36a, 36b can connect an electrode of the BAW device 1 to one or more other BAW devices, one or more integrated passive devices, one or more other circuit elements, one or more signal ports, one or more voltage potentials (for example, ground or power), the like, or any suitable combination thereof. The metal layers 34a and 36a can be electrically connected to the first electrode 18, and the metal layers 34b and 36b can be electrically connected to the second electrode 24. Portions of an adhesion layer 38a and 38b can be positioned between the corresponding metal layer 38a, 38b and an underlying layer (e.g., the piezoelectric layer 20 or the second electrode 24) to increase adhesion between the layers. The adhesion layer can be a titanium layer, for example.

The temperature compensation layer 22 can be positioned in any suitable locations in a BAW device stack. FIGS. 1B to 1H are schematic cross-sectional side views of a portion of an active region of different BAW device stack configurations.

In FIG. 1B, the BAW device stack includes a passivation layer 14, a first electrode 18 over the passivation layer 14, a piezoelectric layer 20 over the first electrode 18, a temperature compensation layer 22 over the piezoelectric layer 20, and a second electrode 24 over the temperature compensation layer 22. The passivation layer 14 can function as a seed layer for the first electrode 18.

In FIG. 1C, the BAW device stack includes a passivation layer 14, a first electrode 18 over the passivation layer 14, a piezoelectric layer 20 over the first electrode 18, a second electrode 24 over the piezoelectric layer 20, and a temperature compensation layer 22 over the second electrode layer 24.

In FIG. 1D, the BAW device stack includes a passivation layer 14, a first electrode 18 over the passivation layer 14, a piezoelectric layer 20 over the first electrode 18, a second electrode 24 over the piezoelectric layer 20, a temperature compensation layer 22 over the second electrode layer 24, and a third electrode layer 25 over the temperature compensation layer 22. The third electrode layer 25 can be electrically connected to the second electrode 24 outside of the illustrated portion of the BAW device stack of FIG. 1D. Accordingly, the temperature compensation layer 22 can be embedded in an upper electrode of the BAW device. The third electrode layer 25 and the second electrode 24 can together form the upper electrode of the BAW device.

In FIG. 1E, the BAW device stack includes a passivation layer 14, a first electrode 18 over the passivation layer 14, a temperature compensation layer 22 over the first electrode 18, a piezoelectric layer 20 over the temperature compensation layer 22, and a second electrode 24 over the piezoelectric layer 20. In some embodiments, the temperature compensation layer 22 can be relatively thin. For example, the temperature compensation layer 22 can be thinner than the first electrode 18 or the second electrode 24. In some other embodiments, the temperature compensation layer 22 can be relatively thick. For example, the temperature compensation layer 22 can be thicker than the first electrode 18 or the second electrode 24.

In FIG. 1F, the BAW device stack includes a passivation layer 14, a first electrode 18 over the passivation layer 14, a first temperature compensation layer 22a over the first electrode 18, a piezoelectric layer 20 over the first temperature compensation layer 22a, a second electrode 24 over the piezoelectric layer 20, a second temperature compensation layer 22b over the second electrode 24, a third electrode layer 25 over the second temperature compensation layer 22b, and a fourth electrode layer 23 between the first temperature compensation layer 22a and the piezoelectric layer 20. The third electrode layer 25 can be electrically connected to the second electrode 24 outside of the illustrated portion of the BAW device stack of FIG. 1F. Accordingly, the temperature compensation layer 22b can be embedded in an upper electrode of the BAW device. The third electrode layer 25 and the second electrode 24 can together form the upper electrode of the BAW device. The fourth electrode layer 23 can be electrically connected to the first electrode 18 outside of the illustrated portion of the BAW device stack of FIG. 1F. Accordingly, the temperature compensation layer 22a can be embedded in a lower electrode of the BAW device. The fourth electrode layer 23 and the first electrode 18 can together form the lower electrode of the BAW device.

In FIG. 1G, the temperature compensation layer 22 is positioned in or embedded in the piezoelectric layer 20. The combination of the piezoelectric layer 20 and the temperature compensation layer 22 can be positioned between the first and second electrodes 18, 24.

In FIG. 1H, the temperature compensation layer 22 is positioned below the first electrode 18. The temperature compensation layer 22 can be positioned between the passivation layer 14 and the first electrode 18.

FIG. 1I is a schematic top plan view of a BAW device according to an embodiment. FIG. 1I can be an example top plan view of the BAW device 1 of FIG. 1A. The top plan view shows an acoustically active region AR and a peripheral region PR. ABAW device can include a frame structure in the peripheral region PR. The frame structure can include a raised frame structure and/or a recessed frame structure.

Any suitable number of temperature compensation layer(s) can be provided at any suitable location in a BAW device stack. The BAW device 1 with the temperature compensation layer 22 can overcome the above-described technical challenges, among others, related to using a silicon oxide layer as a temperature compensation layer. For example, a third order harmonic of a BAW device 1 with the temperature compensation layer 22 can be suppressed relative to the same BAW device with a fused silica temperature compensation layer. The BAW device 1 with the temperature compensation layer 22 can be suited for relatively high power applications. Any suitable principles and advantages related to a temperature compensation layer disclosed herein can be implemented in any other suitable types of acoustic wave devices such as SAW devices, boundary acoustic wave devices, Lamb wave resonators, or the like.

FIG. 2 is a schematic cross-sectional side view of a BAW device 2 according to an embodiment. Unless otherwise noted, the components of the BAW device 2 shown in FIG. 2 may be structurally and/or functionally the same as or generally similar to like components disclosed herein. The BAW device 2 is generally similar to the BAW device 1 of FIG. 1A. However, in the BAW device 2, the raised frame structure 30 includes a raised frame layer 32a positioned between the piezoelectric layer 20 and the temperature compensation layer 22. The raised frame structure 30 is a multi-layer raised frame structure in the BAW device 2.

A change in the relative concentrations of oxide and nitrogen in a silicon oxynitride temperature compensation layer can relate to, for example, the resonant frequency (fs), the quality factor at the resonant frequency (Qs), the quality factor at the anti-resonant frequency (Qp), and the coupling coefficient kt² of the BAW device that implements the temperature compensation layer.

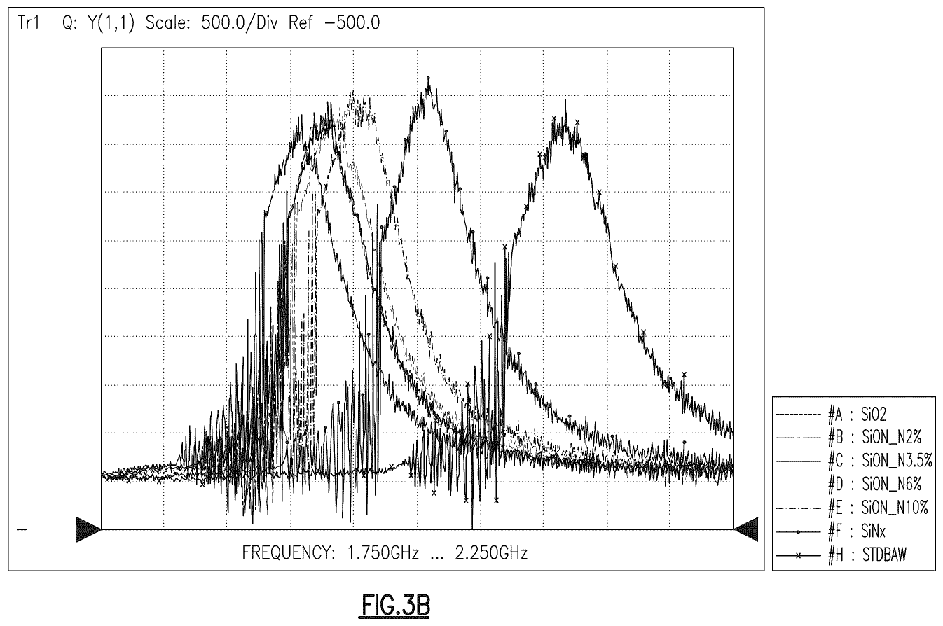

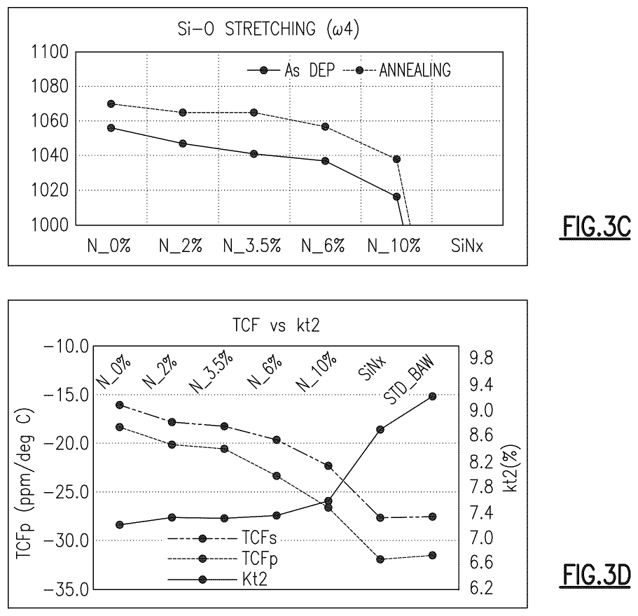

FIG. 3A is a graph showing measurement data for BAW devices (BAW devices A-F) having a temperature compensation layer. The BAW devices used in the measurements of FIG. 3A have the same stack arrangement as the BAW device 2 of FIG. 2. In the measurements of FIG. 3A, a silicon dioxide layer temperature compensation layer, four different concentrations of oxide and nitrogen in a silicon oxynitride temperature compensation layer, and a silicon nitride temperature compensation layer were used: (1) SiO₂ (0% nitrogen concentration); (2) SiON with 2% nitrogen concentration; (3) SiON with 3.5% nitrogen concentration; (4) SiON with 6% nitrogen concentration; (5) SiON with 10% nitrogen concentration; and (6) SiN (0% oxygen concentration). In these measurements, the temperature compensation layers had the same thickness. The BAW device A includes the temperature compensation layer including SiO₂; the BAW device B includes the temperature compensation layer including 2% nitrogen concentration; the BAW device C includes the temperature compensation layer including 3.5% nitrogen concentration; the BAW device D includes the temperature compensation layer including 6% nitrogen concentration; the BAW device E includes the temperature compensation layer including 10% nitrogen concentration; and the BAW device F includes the temperature compensation layer including SiN.

FIG. 3B is a graph showing measured quality factors of the BAW devices A-F used in the measurements of FIG. 3A and a BAW device that does not include a temperature compensation layer (BAW device H). FIG. 3C is a graph showing measured Si—O stretching of the BAW devices used in the measurements of FIG. 3B. FIG. 3D is a graph showing measured TCF and kt² of the BAW devices used in the measurements of FIG. 3B.

The measurement data of FIGS. 3A and 3B indicate that the resonant frequency (fs) and the coupling coefficient kt² generally increase as the nitrogen concentration is increased. The measurement data of FIGS. 3A and 3B also indicate that the resonant frequency (Qs) and the quality factor at the anti-resonant frequency (Qp) generally increase as the nitrogen concentration is increased up to a certain point and the resonant frequency (Qs) and the quality factor at the anti-resonant frequency (Qp) decrease when the temperature compensation layer is SiN. The measurement results indicate that Q values are generally desirable for BAW devices A-F, with the devices D and E having the highest Q values.

The measurement data of FIG. 3D indicate that the TCF of the BAW devices are closer to zero when the nitrogen concentration is lower and the coupling coefficient kt² is higher when the nitrogen concentration is higher. The measurement data of FIG. 3D indicate that the nitrogen concentration in a range between 2% and 10% can provide both a relatively small TCF magnitude and a relatively high coupling coefficient kt².

In some embodiments, the temperature compensation layer 22 can be provided within or embedded in a layer of a BAW device. For example, the temperature compensation layer 22 can be provided within one of the electrodes or the piezoelectric layer. Alternatively or additionally, the temperature compensation layer 22 may be patterned in some embodiments. In some applications, a temperature compensation layer 22 can be embedded in each of the electrodes 18, 24 of a BAW device.

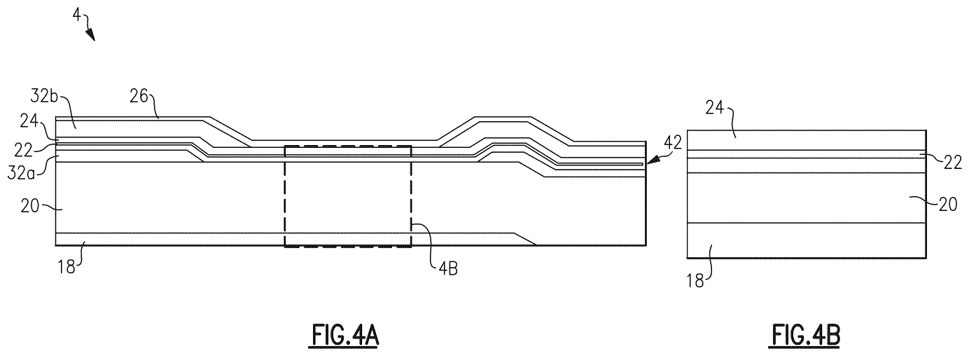

FIG. 4A is a schematic cross-sectional side view of a BAW device 4 according to an embodiment. FIG. 4B is an enlarged view of the BAW device 4 of FIG. 4A. Unless otherwise noted, the components of the BAW device 4 shown in FIGS. 4A and 4B may be structurally and/or functionally the same as or generally similar to like components disclosed herein. The BAW device 4 is generally similar to the BAW device 2 of FIG. 2. However, in the BAW device 4, the temperature compensation layer 22 is provided or embedded within the second electrode 24. As shown in FIG. 4A, upper and lower portions of the second electrode 24 are electrically connected to each other at an edge 42 or peripheral area of the BAW device 4. Electrically connecting metal layers of the second electrode 24 on opposing sides of the temperature compensation layer 22 can increase Qs relative to the BAW device 2 of FIG. 2.

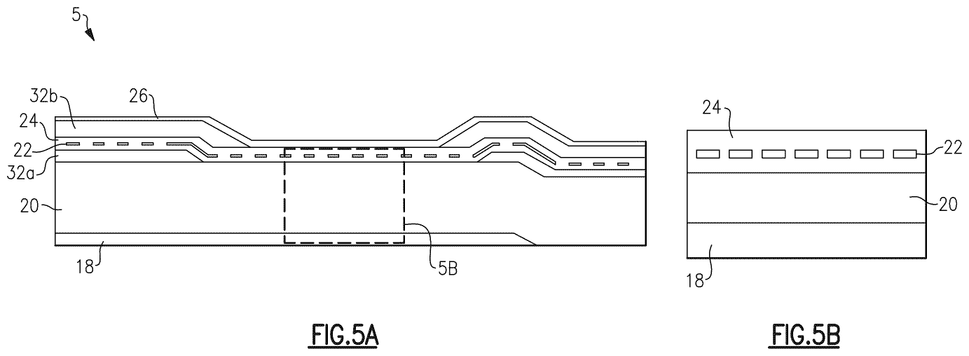

FIG. 5A is a schematic cross-sectional side view of a BAW device 5 according to an embodiment. FIG. 5B is an enlarged view of the BAW device 5 of FIG. 5A. Unless otherwise noted, the components of the BAW device 5 shown in FIGS. 5A and 5B may be structurally and/or functionally the same as or generally similar to like components disclosed herein. The BAW device 5 is generally similar to the BAW device 4 of FIGS. 4A and 4B. However, in the BAW device 5, the temperature compensation layer 22 is patterned. In contrast, the temperature compensation layer 22 in the BAW device 4 of FIGS. 4A and 4B is continuous. With the patterned temperature compensation layer 22 embedded in the second electrode 24, Qs can be increased relative to the BAW device 2 of FIG. 2.

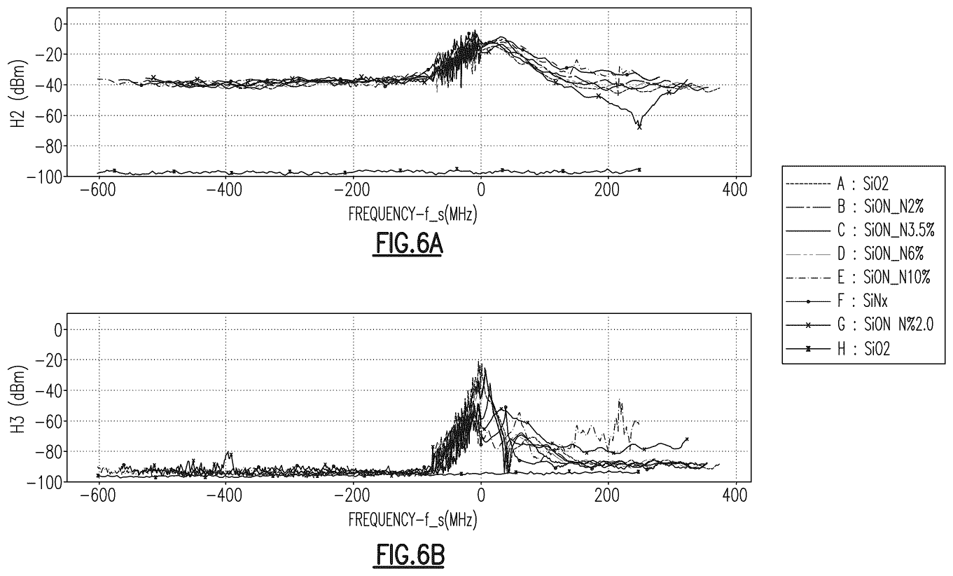

FIGS. 6A and 6B are graphs showing second and third harmonic mode frequency responses of the six BAW devices A-F of FIG. 3A and two BAW devices (BAW devices G and H) with a patterned temperature compensation layer. The BAW device G is an example of the BAW device 5 of FIGS. 5A and 5B. The BAW device G includes a patterned SiON layer with a 2% nitrogen concentration used as the temperature compensation layer 22. The BAW device H is structurally similar to the BAW device 5 of FIGS. 5A and 5B. However, the BAW device H includes a patterned SiO₂ layer in place of the temperature compensation layer 22.

The curves of FIGS. 6A and 6B indicate that in the second and third harmonic modes, a greater concentration of nitrogen (e.g., 10% nitrogen concentration) can suppress these harmonic modes to improve the frequency response more than a lower nitrogen concentration (e.g., 0% nitrogen concentration). Also, the curves of FIGS. 6A and 6B indicate that, although the BAW devices G and H with the patterned temperature compensation layers can provide a higher power, noise can appear in the frequency response.

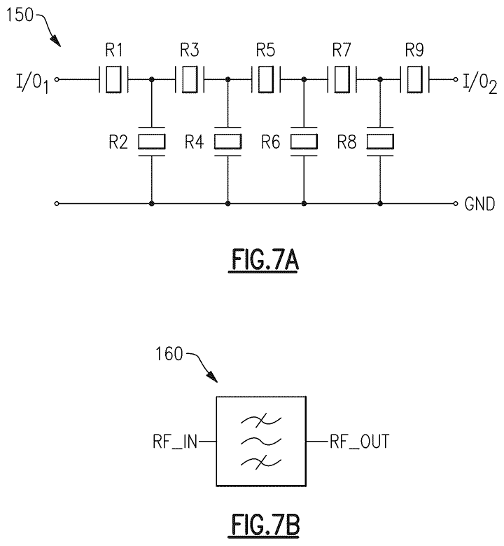

Acoustic wave devices disclosed herein can be implemented as acoustic wave resonators in a variety of filters. Such filters can be arranged to filter a radio frequency signal. Acoustic wave devices disclosed herein can be implemented in a variety of different filter topologies. Example filter topologies include without limitation, ladder filters, lattice filters, hybrid ladder lattice filters, notch filters where a notch is created by an acoustic wave resonator, hybrid acoustic and non-acoustic inductor-capacitor filters, and the like. The example filter topologies can implement band pass filters. The example filter topologies can implement band stop filters. In some instances, acoustic wave devices disclosed herein can be implemented in filters with one or more other types of resonators and/or with passive impedance elements, such as one or more inductors and/or one or more capacitors. An example filter topology will be discussed with reference to FIG. 7A.

FIG. 7A is a schematic diagram of a ladder filter 150 that includes an acoustic wave resonator according to an embodiment. The ladder filter 150 is an example topology that can implement a band pass filter formed of acoustic wave resonators. In a band pass filter with a ladder filter topology, the shunt resonators can have lower resonant frequencies than the series resonators. The ladder filter 150 can be arranged to filter a radio frequency signal. As illustrated, the ladder filter 150 includes series acoustic wave resonators R1 R3, R5, R7, and R9 and shunt acoustic wave resonators R2, R4, R6, and R8 coupled between a first input/output port I/O₁ and a second input/output port I/O₂. Any suitable number of series acoustic wave resonators can be in included in a ladder filter. Any suitable number of shunt acoustic wave resonators can be included in a ladder filter. The first input/output port I/O₁ can be a transmit port and the second input/output port I/O₂ can be an antenna port. Alternatively, first input/output port I/O₁ can be a receive port and the second input/output port I/O₂ can be an antenna port. One or more of the acoustic wave resonators of the ladder filter 150 can include an acoustic wave device including a silicon oxynitride layer in accordance with any suitable principles and advantages disclosed herein. All acoustic resonators of the ladder filter 150 can include a silicon oxynitride layer in accordance with any suitable principles and advantages disclosed herein in certain applications.

A filter that includes an acoustic wave resonator in accordance with any suitable principles and advantages disclosed herein be arranged to filter a radio frequency signal in a fifth generation 5G NR operating band within Frequency Range 1 (FR1). FR1 can be from 410 MHz to 7.125 gigahertz (GHz), for example, as specified in a current 5G NR specification. A filter that an acoustic wave resonator in accordance with any suitable principles and advantages disclosed herein can be arranged to filter a radio frequency signal in a fourth generation (4G) Long Term Evolution (LTE) operating band. A filter that includes an acoustic wave resonator in accordance with any suitable principles and advantages disclosed herein can be included in a filter having a passband that includes a 4G LTE operating band and a 5G NR operating band. Such a filter can be implemented in a dual connectivity application, such as an E-UTRAN New Radio-Dual Connectivity (ENDC) application. A multiplexer including any such filters can include one or more other filters with a passband corresponding to a 5G NR operating band and/or a 4G LTE operating band. A filter that includes an acoustic wave resonator in accordance with any suitable principles and advantages disclosed herein can be arranged to filter a radio frequency signal in any other suitable operating band, such as a WiFi operating band, a Global Positioning System (GPS) operating band, a Bluetooth operating band, a ZigBee operating band, a WiMax operating band, etc.

FIG. 7B is schematic diagram of an acoustic wave filter 160. The acoustic wave filter 160 can include the acoustic wave resonators of the ladder filter 150. The acoustic wave filter 160 is a band pass filter. The acoustic wave filter 160 is arranged to filter a radio frequency signal. The acoustic wave filter 160 includes one or more acoustic wave devices coupled between a first input/output port RF_IN and a second input/output port RF_OUT. The acoustic wave filter 160 includes an acoustic wave resonator according to an embodiment.

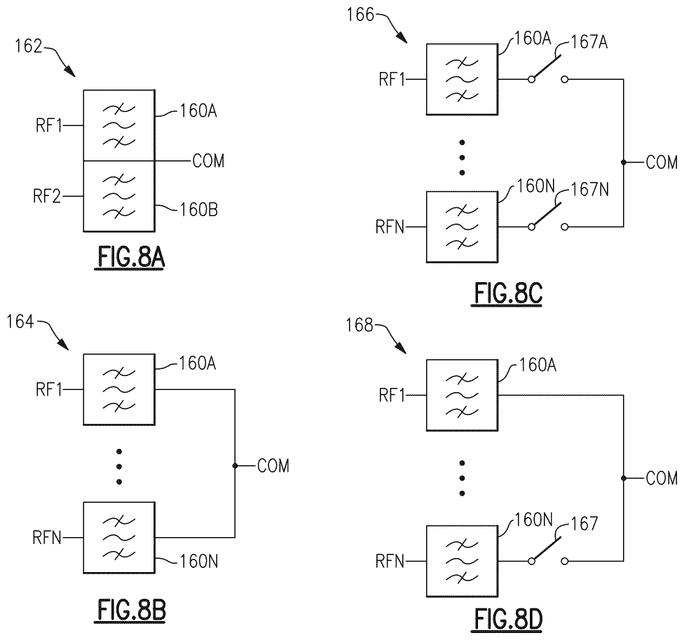

The acoustic wave devices disclosed herein can be implemented in a standalone filter and/or in a filter of any suitable multiplexer. Such filters can be any suitable topology, such as a ladder filter topology. The filter can be a band pass filter arranged to filter a 4G LTE band and/or 5G NR band. Example multiplexers will be discussed with reference to FIGS. 8A to 8D. Any suitable principles and advantages of these multiplexers can be implemented together with each other.

FIG. 8A is a schematic diagram of a duplexer 162 that includes an acoustic wave filter according to an embodiment. The duplexer 162 includes a first filter 160A and a second filter 160B coupled to together at a common node COM. One of the filters of the duplexer 162 can be a transmit filter and the other of the filters of the duplexer 162 can be a receive filter. In some other instances, such as in a diversity receive application, the duplexer 162 can include two receive filters. Alternatively, the duplexer 162 can include two transmit filters. The common node COM can be an antenna node.

The first filter 160A is an acoustic wave filter arranged to filter a radio frequency signal. The first filter 160A includes one or more acoustic wave resonators coupled between a first radio frequency node RF1 and the common node COM. The first radio frequency node RF1 can be a transmit node or a receive node. The first filter 160A includes an acoustic wave resonator in accordance with any suitable principles and advantages disclosed herein.

The second filter 160B can be any suitable filter arranged to filter a second radio frequency signal. The second filter 160B can be, for example, an acoustic wave filter, an acoustic wave filter that includes an acoustic wave resonator with at least one silicon oxynitride layer in accordance with any suitable principles and advantages disclosed herein, an LC filter, a hybrid acoustic wave LC filter, or the like. The second filter 160B is coupled between a second radio frequency node RF2 and the common node. The second radio frequency node RF2 can be a transmit node or a receive node.

Although example embodiments may be discussed with filters or duplexers for illustrative purposes, any suitable principles and advantages disclosed herein can be implement in a multiplexer that includes a plurality of filters coupled together at a common node. Examples of multiplexers include but are not limited to a duplexer with two filters coupled together at a common node, a triplexer with three filters coupled together at a common node, a quadplexer with four filters coupled together at a common node, a hexaplexer with six filters coupled together at a common node, an octoplexer with eight filters coupled together at a common node, or the like. Multiplexers can include filters having different passbands. Multiplexers can include any suitable number of transmit filters and any suitable number of receive filters. For example, a multiplexer can include all receive filters, all transmit filters, or one or more transmit filters and one or more receive filters. One or more filters of a multiplexer can include any suitable number of acoustic wave devices in accordance with any suitable principles and advantages disclosed herein.

FIG. 8B is a schematic diagram of a multiplexer 164 that includes an acoustic wave filter according to an embodiment. The multiplexer 164 includes a plurality of filters 160A to 160N coupled together at a common node COM. The plurality of filters can include any suitable number of filters including, for example, 3 filters, 4 filters, 5 filters, 6 filters, 7 filters, 8 filters, or more filters. Some or all of the plurality of acoustic wave filters can be acoustic wave filters. As illustrated, the filters 160A to 160N each have a fixed electrical connection to the common node COM. This can be referred to as hard multiplexing or fixed multiplexing. Filters have fixed electrical connections to the common node in hard multiplexing applications.

The first filter 160A is an acoustic wave filter arranged to filter a radio frequency signal. The first filter 160A can include one or more acoustic wave devices coupled between a first radio frequency node RF1 and the common node COM. The first radio frequency node RF1 can be a transmit node or a receive node. The first filter 160A includes an acoustic wave resonator in accordance with any suitable principles and advantages disclosed herein. The other filter(s) of the multiplexer 164 can include one or more acoustic wave filters, one or more acoustic wave filters that include an acoustic wave resonator in accordance with any suitable principles and advantages disclosed herein, one or more LC filters, one or more hybrid acoustic wave LC filters, the like, or any suitable combination thereof.

FIG. 8C is a schematic diagram of a multiplexer 166 that includes an acoustic wave filter according to an embodiment. The multiplexer 166 is like the multiplexer 164 of FIG. 8B, except that the multiplexer 166 implements switched multiplexing. In switched multiplexing, a filter is coupled to a common node via a switch. In the multiplexer 166, the switches 167A to 167N can selectively electrically connect respective filters 160A to 160N to the common node COM. For example, the switch 167A can selectively electrically connect the first filter 160A the common node COM via the switch 167A. Any suitable number of the switches 167A to 167N can electrically a respective filter 160A to 160N to the common node COM in a given state. Similarly, any suitable number of the switches 167A to 167N can electrically isolate a respective filter 160A to 160N to the common node COM in a given state. The functionality of the switches 167A to 167N can support various carrier aggregations.

FIG. 8D is a schematic diagram of a multiplexer 168 that includes an acoustic wave filter according to an embodiment. The multiplexer 168 illustrates that a multiplexer can include any suitable combination of hard multiplexed and switched multiplexed filters. One or more acoustic wave devices in accordance with any suitable principles and advantages disclosed herein can be included in a filter (e.g., the filter 160A) that is hard multiplexed to the common node COM of the multiplexer 168. Alternatively or additionally, one or more acoustic wave devices in accordance with any suitable principles and advantages disclosed herein can be included in a filter (e.g., the filter 160N) that is switch multiplexed to the common node COM of the multiplexer 168.

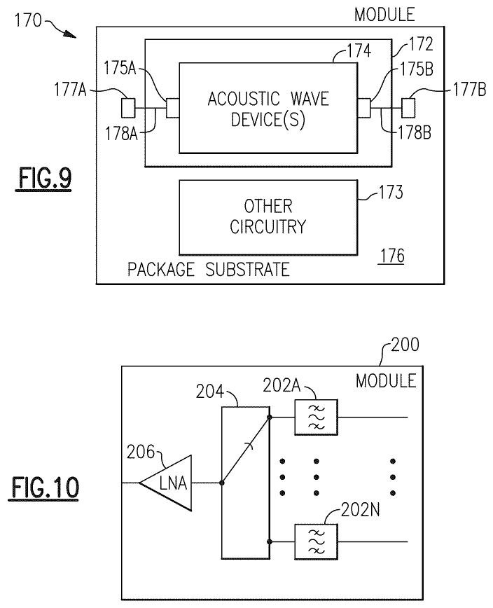

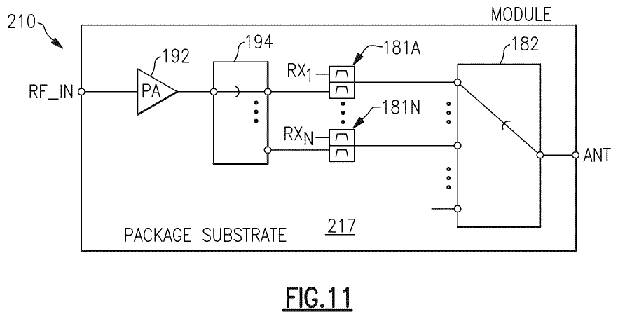

Acoustic wave devices disclosed herein can be implemented in a variety of packaged modules. Some example packaged modules will now be disclosed in which any suitable principles and advantages of the acoustic wave devices disclosed herein can be implemented. The example packaged modules can include a package that encloses the illustrated circuit elements. A module that includes a radio frequency component can be referred to as a radio frequency module. The illustrated circuit elements can be disposed on a common packaging substrate. The packaging substrate can be a laminate substrate, for example. FIGS. 9 to 11 are schematic block diagrams of illustrative packaged modules according to certain embodiments. Any suitable combination of features of these packaged modules can be implemented with each other.

FIG. 9 is a schematic diagram of a radio frequency module 170 that includes an acoustic wave component 172 according to an embodiment. The illustrated radio frequency module 170 includes the acoustic wave component 172 and other circuitry 173. The acoustic wave component 172 can include an acoustic wave filter that includes a plurality of acoustic wave devices, for example. The acoustic wave devices can be BAW devices in certain applications.

The acoustic wave component 172 shown in FIG. 9 includes one or more acoustic wave devices 174 and terminals 175A and 175B. The one or more acoustic wave devices 174 include at least one acoustic wave device implemented in accordance with any suitable principles and advantages disclosed herein. The terminals 175A and 174B can serve, for example, as an input contact and an output contact. Although two terminals are illustrated, any suitable number of terminals can be implemented for a particular application. The acoustic wave component 172 and the other circuitry 173 are on a common packaging substrate 176 in FIG. 9. The packaging substrate 176 can be a laminate substrate. The terminals 175A and 175B can be electrically connected to contacts 177A and 177B, respectively, on the packaging substrate 176 by way of electrical connectors 178A and 178B, respectively. The electrical connectors 178A and 178B can be bumps or wire bonds, for example.

The other circuitry 173 can include any suitable additional circuitry. For example, the other circuitry can include one or more radio frequency amplifiers (e.g., one or more power amplifiers and/or one or more low noise amplifiers), one or more radio frequency switches, one or more additional filters, one or more radio frequency (RF) couplers, one or more delay lines, one or more phase shifters, the like, or any suitable combination thereof. Accordingly, the other circuitry 173 can include one or more radio frequency circuit elements. The other circuitry 173 can be radio frequency circuitry. The other circuitry 173 can be electrically connected to the one or more acoustic wave devices 174. The radio frequency module 170 can include one or more packaging structures to, for example, provide protection and/or facilitate easier handling of the radio frequency module 170. Such a packaging structure can include an overmold structure formed over the packaging substrate 176. The overmold structure can encapsulate some or all of the components of the radio frequency module 170.

FIG. 10 is a schematic block diagram of a module 200 that includes filters 202A to 202N, a radio frequency switch 204, and a low noise amplifier 206 according to an embodiment. One or more filters of the filters 202A to 202N can include any suitable number of acoustic wave devices in accordance with any suitable principles and advantages disclosed herein. Any suitable number of filters 202A to 202N can be implemented. The illustrated filters 202A to 202N are receive filters. One or more of the filters 202A to 202N can be included in a multiplexer that also includes a transmit filter and/or another receive filter. The radio frequency switch 204 can be a multi-throw radio frequency switch. The radio frequency switch 204 can electrically couple an output of a selected filter of filters 202A to 202N to the low noise amplifier 206. In some embodiments, a plurality of low noise amplifiers can be implemented. The module 200 can include diversity receive features in certain applications.

FIG. 11 is a schematic diagram of a radio frequency module 210 that includes an acoustic wave filter according to an embodiment. As illustrated, the radio frequency module 210 includes duplexers 181A to 181N, a power amplifier 192, a radio frequency switch 194 configured as a select switch, and an antenna switch 182. The radio frequency module 210 can include a package that encloses the illustrated elements. The illustrated elements can be disposed on a common packaging substrate 217. The packaging substrate 217 can be a laminate substrate, for example. A radio frequency module that includes a power amplifier can be referred to as a power amplifier module. A radio frequency module can include a subset of the elements illustrated in FIG. 11 and/or additional elements. The radio frequency module 210 may include any one of the acoustic wave filters that include at least one acoustic wave resonator in accordance with any suitable principles and advantages disclosed herein.

The duplexers 181A to 181N can each include two acoustic wave filters coupled to a common node. For example, the two acoustic wave filters can be a transmit filter and a receive filter. As illustrated, the transmit filter and the receive filter can each be a band pass filter arranged to filter a radio frequency signal. One or more of the transmit filters can include an acoustic wave device in accordance with any suitable principles and advantages disclosed herein. Similarly, one or more of the receive filters can include an acoustic wave device in accordance with any suitable principles and advantages disclosed herein. Although FIG. 11 illustrates duplexers, any suitable principles and advantages disclosed herein can be implemented in other multiplexers (e.g., quadplexers, hexaplexers, octoplexers, etc.) and/or in switched multiplexers and/or with standalone filters.

The power amplifier 192 can amplify a radio frequency signal. The illustrated radio frequency switch 194 is a multi-throw radio frequency switch. The radio frequency switch 194 can electrically couple an output of the power amplifier 192 to a selected transmit filter of the transmit filters of the duplexers 181A to 181N. In some instances, the radio frequency switch 194 can electrically connect the output of the power amplifier 192 to more than one of the transmit filters. The antenna switch 182 can selectively couple a signal from one or more of the duplexers 181A to 181N to an antenna port ANT. The duplexers 181A to 181N can be associated with different frequency bands and/or different modes of operation (e.g., different power modes, different signaling modes, etc.).

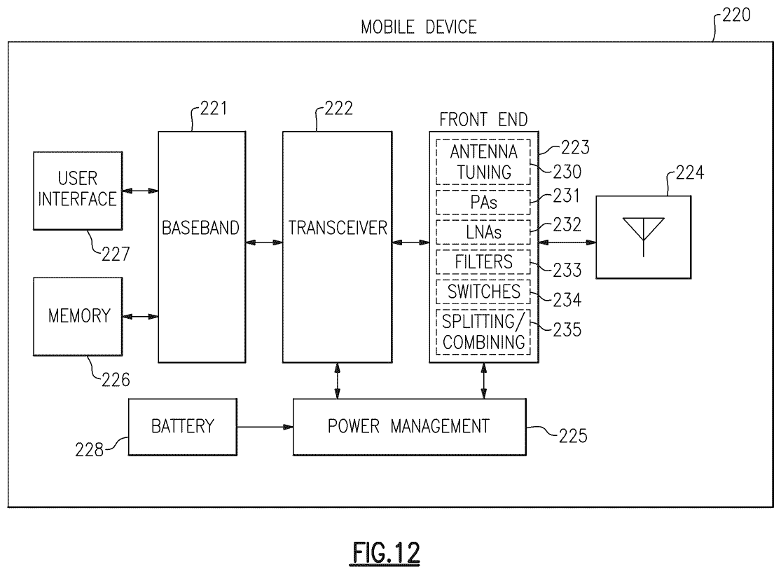

The acoustic wave devices disclosed herein can be implemented in wireless communication devices. FIG. 12 is a schematic block diagram of a wireless communication device 220 that includes an acoustic wave device according to an embodiment. The wireless communication device 220 can be a mobile device. The wireless communication device 220 can be any suitable wireless communication device. For instance, a wireless communication device 220 can be a mobile phone, such as a smart phone. As illustrated, the wireless communication device 220 includes a baseband system 221, a transceiver 222, a front end system 223, one or more antennas 224, a power management system 225, a memory 226, a user interface 227, and a battery 228.

The wireless communication device 220 can be used communicate using a wide variety of communications technologies, including, but not limited to, 2G, 3G, 4G (including LTE, LTE-Advanced, and/or LTE-Advanced Pro), 5G NR, WLAN (for instance, Wi-Fi), WPAN (for instance, Bluetooth and/or ZigBee), WMAN (for instance, WiMax), and/or GPS technologies.

The transceiver 222 generates RF signals for transmission and processes incoming RF signals received from the antennas 224. Various functionalities associated with the transmission and receiving of RF signals can be achieved by one or more components that are collectively represented in FIG. 12 as the transceiver 222. In one example, separate components (for instance, separate circuits or dies) can be provided for handling certain types of RF signals.

The front end system 223 aids in conditioning signals provided to and/or received from the antennas 224. In the illustrated embodiment, the front end system 223 includes antenna tuning circuitry 230, power amplifiers (PAS) 231, low noise amplifiers (LNAs) 232, filters 233, switches 234, and signal splitting/combining circuitry 235. However, other implementations are possible. The filters 233 can include one or more acoustic wave filters that include any suitable number of acoustic wave devices in accordance with any suitable principles and advantages disclosed herein.

For example, the front end system 223 can provide a number of functionalities, including, but not limited to, amplifying signals for transmission, amplifying received signals, filtering signals, switching between different bands, switching between different power modes, switching between transmission and receiving modes, duplexing of signals, multiplexing of signals, or any suitable combination thereof.

In certain implementations, the wireless communication device 220 supports carrier aggregation, thereby providing flexibility to increase peak data rates. Carrier aggregation can be used for Frequency Division Duplexing (FDD) and/or Time Division Duplexing (TDD), and may be used to aggregate a plurality of carriers and/or channels. Carrier aggregation includes contiguous aggregation, in which contiguous carriers within the same operating frequency band are aggregated. Carrier aggregation can also be non-contiguous, and can include carriers separated in frequency within a common band or in different bands.

The antennas 224 can include antennas used for a wide variety of types of communications. For example, the antennas 224 can include antennas for transmitting and/or receiving signals associated with a wide variety of frequencies and communications standards.

In certain implementations, the antennas 224 support MIMO communications and/or switched diversity communications. For example, MIMO communications use multiple antennas for communicating multiple data streams over a single radio frequency channel. MIMO communications benefit from higher signal to noise ratio, improved coding, and/or reduced signal interference due to spatial multiplexing differences of the radio environment. Switched diversity refers to communications in which a particular antenna is selected for operation at a particular time. For example, a switch can be used to select a particular antenna from a group of antennas based on a variety of factors, such as an observed bit error rate and/or a signal strength indicator.

The wireless communication device 220 can operate with beamforming in certain implementations. For example, the front end system 223 can include amplifiers having controllable gain and phase shifters having controllable phase to provide beam formation and directivity for transmission and/or reception of signals using the antennas 224. For example, in the context of signal transmission, the amplitude and phases of the transmit signals provided to the antennas 224 are controlled such that radiated signals from the antennas 224 combine using constructive and destructive interference to generate an aggregate transmit signal exhibiting beam-like qualities with more signal strength propagating in a given direction. In the context of signal reception, the amplitude and phases are controlled such that more signal energy is received when the signal is arriving to the antennas 224 from a particular direction. In certain implementations, the antennas 224 include one or more arrays of antenna elements to enhance beamforming.

The baseband system 221 is coupled to the user interface 227 to facilitate processing of various user input and output (I/O), such as voice and data. The baseband system 221 provides the transceiver 222 with digital representations of transmit signals, which the transceiver 222 processes to generate RF signals for transmission. The baseband system 221 also processes digital representations of received signals provided by the transceiver 222. As shown in FIG. 12, the baseband system 221 is coupled to the memory 226 of facilitate operation of the wireless communication device 220.

The memory 226 can be used for a wide variety of purposes, such as storing data and/or instructions to facilitate the operation of the wireless communication device 220 and/or to provide storage of user information.

The power management system 225 provides a number of power management functions of the wireless communication device 220. In certain implementations, the power management system 225 includes a PA supply control circuit that controls the supply voltages of the power amplifiers 231. For example, the power management system 225 can be configured to change the supply voltage(s) provided to one or more of the power amplifiers 231 to improve efficiency, such as power added efficiency (PAE).

As shown in FIG. 12, the power management system 225 receives a battery voltage from the battery 228. The battery 228 can be any suitable battery for use in the wireless communication device 220, including, for example, a lithium-ion battery.

Any of the embodiments described above can be implemented in association with mobile devices such as cellular handsets. The principles and advantages of the embodiments can be used for any systems or apparatus, such as any uplink wireless communication device, that could benefit from any of the embodiments described herein. The teachings herein are applicable to a variety of systems. Although this disclosure includes example embodiments, the teachings described herein can be applied to a variety of structures. Any of the principles and advantages discussed herein can be implemented in association with RF circuits configured to process signals having a frequency in a range from about 30 kHz to 300 GHz, such as in a frequency range from about 400 MHz to 8.5 GHZ, in a frequency range from about 2 GHz to 10 GHz, or in a frequency range from 5 GHz to 20 GHz.

Aspects of this disclosure can be implemented in various electronic devices. Examples of the electronic devices can include, but are not limited to, consumer electronic products, parts of the consumer electronic products such as packaged radio frequency modules, uplink wireless communication devices, wireless communication infrastructure, electronic test equipment, etc. Examples of the electronic devices can include, but are not limited to, a mobile phone such as a smart phone, a wearable computing device such as a smart watch or an ear piece, a telephone, a television, a computer monitor, a computer, a modem, a hand-held computer, a laptop computer, a tablet computer, a microwave, a refrigerator, a vehicular electronics system such as an automotive electronics system, a robot such as an industrial robot, an Internet of things device, a stereo system, a digital music player, a radio, a camera such as a digital camera, a portable memory chip, a home appliance such as a washer or a dryer, a peripheral device, a wrist watch, a clock, etc. Further, the electronic devices can include unfinished products.

Unless the context indicates otherwise, throughout the description and the claims, the words “comprise,” “comprising,” “include,” “including” and the like are to generally be construed in an inclusive sense, as opposed to an exclusive or exhaustive sense; that is to say, in the sense of “including, but not limited to.” Conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively.

While certain embodiments have been described, these embodiments have been presented by way of example only, and are not intended to limit the scope of the disclosure. Indeed, the novel resonators, filters, multiplexer, devices, modules, wireless communication devices, apparatus, methods, and systems described herein may be embodied in a variety of other forms. Furthermore, various omissions, substitutions, and changes in the form of the resonators, filters, multiplexer, devices, modules, wireless communication devices, apparatus, methods, and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and/or acts of the various embodiments described above can be combined to provide further embodiments. The accompanying claims and their equivalents are intended to cover such forms or modifications as would fall within the scope and spirit of the disclosure.

What is claimed is:

1. A bulk acoustic wave device comprising:
electrodes including a first electrode and a second electrode;
a piezoelectric layer between the first electrode and the second electrode; and
a temperature compensation layer in thermal communication with the piezoelectric layer, the temperature compensation layer including a silicon oxide composite that includes silicon oxide and a stiffening agent, and the temperature compensation layer having a positive temperature coefficient of variation.

2. The bulk acoustic wave device of claim 1 wherein the stiffening agent includes nitrogen.

3. The bulk acoustic wave device of claim 1 wherein the stiffening agent has a greater electronegativity than carbon.

4. The bulk acoustic wave device of claim 1 wherein the temperature compensation layer is positioned between the piezoelectric layer and one of the electrodes.

5. The bulk acoustic wave device of claim 1 wherein the temperature compensation layer is positioned between a surface of the first electrode and a surface of the second electrode.

6. The bulk acoustic wave device of claim 1 wherein one of the electrodes is positioned between the temperature compensation layer and the piezoelectric layer.

7. The bulk acoustic wave device of claim 1 wherein the temperature compensation layer is embedded in one of the electrodes, the one electrode includes a first portion and a second portion that are electrically connected to each other, and the first portion being on an opposite side of the temperature compensation layer than the second portion.

8. The bulk acoustic wave device of claim 1 wherein the temperature compensation layer is embedded in the piezoelectric layer.

9. The bulk acoustic wave device of claim 1 wherein the temperature compensation layer is patterned.

10. The bulk acoustic wave device of claim 1 wherein the stiffening agent is configured to suppress a third order harmonic associated with the silicon oxide.

11. The bulk acoustic wave device of claim 1 further comprising a support substrate and an acoustic reflector between the support substrate and the first electrode.

12. A bulk acoustic wave device comprising:
electrodes including a first electrode and a second electrode;
a piezoelectric layer between the first electrode and the second electrode; and
a temperature compensation layer in thermal communication with the piezoelectric layer, the temperature compensation layer including silicon oxynitride, and the temperature compensation layer having a positive temperature coefficient of variation.

13. The bulk acoustic wave device of claim 12 wherein the temperature compensation layer is positioned between the piezoelectric layer and one of the electrodes.

14. The bulk acoustic wave device of claim 12 wherein the temperature compensation layer is positioned between a surface of the first electrode and a surface of the second electrode.

15. The bulk acoustic wave device of claim 12 wherein one of the electrodes is positioned between the temperature compensation layer and the piezoelectric layer.

16. The bulk acoustic wave device of claim 12 wherein the temperature compensation layer is embedded in one of the electrodes, the one electrode includes a first portion and a second portion that are electrically connected to each other, and the first portion being on an opposite side of the temperature compensation layer than the second portion.

17. The bulk acoustic wave device of claim 12 wherein the temperature compensation layer is embedded in the piezoelectric layer.

18. The bulk acoustic wave device of claim 12 wherein the temperature compensation layer is patterned.

19. An acoustic wave filter for filtering a radio frequency signal, the acoustic wave filter comprising:
a bulk acoustic wave device including a first electrode, a second electrode, a piezoelectric layer between the first electrode and the second electrode, and a temperature compensation layer in thermal communication with the piezoelectric layer, the temperature compensation layer including a silicon oxide composite that includes silicon oxide and a stiffening agent, and the temperature compensation layer having a positive temperature coefficient of variation; and
a plurality of additional acoustic wave resonators, the bulk acoustic wave device and the plurality of additional acoustic wave resonators configured to filter the radio frequency signal.

20. The acoustic wave filter of claim 19 wherein the stiffening agent includes nitrogen.
